(19) United States
(12) Patent Application Publication
(10) Pub. No.: US 2006/0039173 A1
(43) Pub. Date: Feb. 23, 2006

(54) Content addressable memory

(75) Inventor: Hideyuki Noda, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/208,613

(22) Filed: Aug. 23, 2005

(30) Foreign Application Priority Data
Aug. 23, 2004 (JP) JP2004-241913

(51) Int. Cl. G11C 15/00

(52) U.S. Cl. 365/49

(57) ABSTRACT

The present invention provides a content addressable memory (CAM) with no problem in operation speed reduction and with small power consumption on an SOI substrate. The CAM includes a data memory part DM and a data comparison part DC which compares data provided on a search line SL with data stored in the data memory part DM. In the case of a mismatch, a match line ML precharged to H level is discharged to be L level. Here, gates and bodies of respective NMOS transistors N6 and N8, which constitute data comparison part DC, are short-circuited to lower threshold voltages of NMOS transistors N6 and N8. Therefore, even if lowering of voltage of search line SL connected to gate is performed, turn-on current of MOS transistors N6 and N8 can be increased to discharge the match line ML with high speed. As a result, even if lowering of power consumption of the search line SL is performed to lower power consumption, a CAM with no problem in operation speed reduction can be realized.

### BACKGROUND OF THE INVENTION

1. Field of the Invention

The present invention relates to a content addressable memory for use in data search or the like.

2. Description of the Background Art

A Content Addressable Memory (alternatively referred to as merely CAM below) is used for data search or the like. The CAM compares data preliminarily stored in a memory array with data inputted from outside to perform search operation.

Further, a conventional technique related to the present invention is disclosed in Japanese Patent Application Laid-Open No. 2002-373493.

The CAM is a memory very suitable for fast search process; however, such a known CAM suffers from a problem in that power consumption in operation is very large due to its parallel operability.

Reducing operating voltage is the most important to reduce the power consumption in operation.

However, if the operating voltage is simply lowered, it becomes difficult to stably hold data stored in a CAM memory cell (CAM cell).

That is, in the case that the CAM cell is deemed as a memory element like a SRAM (Static Random Access Memory), when the operating voltage is lowered, operational allowance in reading will drop out to cause a possibility of data destruction in the worst case.

In addition, if the operating voltage is lowered, a driving speed of a search line or a match line is lowered. As a result, the power consumption of the CAM can be reduced, but there arises a problem in that an operation frequency will drop.

### SUMMARY OF THE INVENTION

It is an object of the present invention to provide a content addressable memory with no problem in operation speed reduction and with small power consumption.

In accordance with a first aspect of the present invention, a content addressable memory formed on an SOI substrate includes a plurality of memory cells, a match line connected to the memory cell, and a search line connected to the memory cell.

The memory cell includes a data memory part, and a data comparison part for comparing data stored in the data memory part with search data provided on the search line.

The data comparison part includes a transistor whose gate is connected to the search line and discharges the match line by conducting.

The transistor has a gate and a body being short-circuited.

According to the present invention, the data comparison part includes a transistor having a gate and a body being short-circuited. Since the threshold voltage of the transistor is lowered by the short-circuit between the gate and the body, turn-on current can be increased even if the voltage of the search line is lowered. Therefore, the match line can discharge fast.

As a result, a content addressable memory with no problem in operation speed reduction can be realized even if the voltage of the search line is lowered to reduce power consumption.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a configuration of a memory cell of a content addressable memory according to a first embodiment;

FIG. 2 is voltage waveforms of a search line and a match line according to the first embodiment;

FIG. 3 is a circuit diagram showing a configuration of a memory cell of a content addressable memory according to a second embodiment;

FIG. 4 is a circuit diagram showing a configuration of a search line driver according to a third embodiment;

FIG. 5 is voltage waveforms showing search data and a search line according to the third embodiment;

FIG. 6 is a block diagram showing a configuration of a content addressable memory according to a fourth embodiment;

FIG. 7 is a circuit diagram showing a configuration of a match line amplifier according to the fourth embodiment;

FIG. 8 is a block diagram showing a configuration of a step-down circuit according to the fourth embodiment;

FIG. 9 is a circuit diagram showing a configuration of a memory cell of a content addressable memory according to a fifth embodiment;

FIG. 10 is a layout view of a memory cell of a content addressable memory according to the fifth embodiment; and

FIG. 11 is a cross-sectional view showing a configuration of a memory cell of a content addressable memory according to the fifth embodiment.

### DESCRIPTION OF THE PREFERRED EMBODIMENTS

### First Embodiment

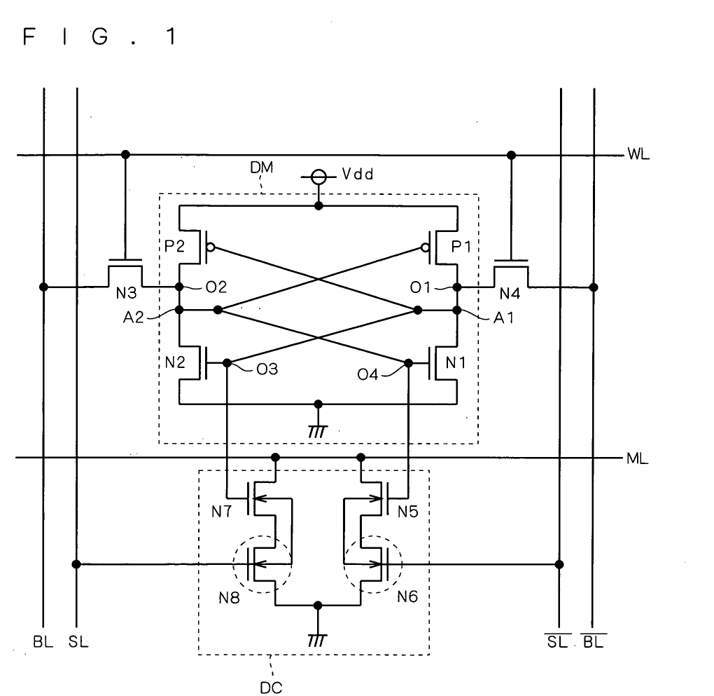

FIG. 1 is a circuit diagram showing one of memory cells of a content addressable memory according to a first embodiment of the present invention. The content addressable memory includes a plurality of memory cells. The memory cell includes a data memory part DM, data stored in the data memory part DM, and a data comparison part DC for comparing search data provided on search lines SL and \overline{SL}. Further, the content addressable memory according to the embodiment is formed using an SOI (Silicon On Insulator) process.

A drain of an NMOS transistor N3 is connected to a drain of a PMOS transistor P2, which constitutes the data memory part DM, at a node O2. A source of the NMOS transistor N3 is connected to a bit line BL and a gate thereof is connected to a word line WL.

A gate of an NMOS transistor N4 is connected to the word line WL. A drain of the NMOS transistor N4 is connected to a drain of a PMOS transistor P1, which constitutes the data memory part DM, at a node 01 and a source thereof is connected to a bit line \overline{BL}.

The data memory part DM has a configuration similar to an ordinary SRAM cell. The configuration of the data memory part DM will be described below.

A source of the PMOS transistor P1 is connected to a power supply voltage Vdd and a drain thereof is connected to a drain of an NMOS transistor N1. Then, a source of the NMOS transistor N1 is grounded. A gate of the PMOS transistor P1 is connected to a gate of the NMOS transistor N1 and together connected to the drain of the PMOS transistor P2 and a drain of an NMOS transistor N2 at a node A2.

A source of the PMOS transistor P2 is connected to the power supply voltage Vdd and the drain thereof is connected to the drain of the NMOS transistor N2. A source of the NMOS transistor N2 is grounded. A gate of the PMOS transistor P2 is connected to a gate of the NMOS transistor N2 and together connected to the drain of the PMOS transistor P1 and the drain of the NMOS transistor N1.

The data comparison part DC is constituted by NMOS transistors N5 to N8. A gate of the NMOS transistor N7 is connected to the gate of the NMOS transistor N2, which constitutes the data memory part DM, at a node O3. Further, a gate of the NMOS transistor N5, which constitutes the data comparison part DM, is connected to the gate of the NMOS transistor N1 of the data memory part DM at a node O4.

A drain of the NMOS transistor N7 is connected to a match line ML and a source thereof is connected to a drain of the NMOS transistor N8. A source of the NMOS transistor N8 is grounded. Further, a gate of the NMOS transistor N8 is connected to the search line SL.

A drain of the NMOS transistor N5 is connected to the match line ML and a source thereof is connected to a drain of the NMOS transistor N6. A source of the NMOS transistor N6 is grounded. Further, a gate of the NMOS transistor N6 is connected to a search line \overline{SL}.

Here, each of the NMOS transistors N6 and N8 (transistors surrounded by broken lines in FIG. 1) of the data comparison part DC has a body (a silicon layer below a channel) short-circuited to the gate thereof. Then, the body of the NMOS transistor N6 is connected to a body of the NMOS transistor N5. Further, the body of the NMOS transistor N8 is connected to a body of the NMOS transistor N7. The search line SL and the \overline{SL} are respectively short-circuited to the bodies of the NMOS transistors N6 and N8.

In the SOI process, the transistor having the gate short-circuited to the body is realized as in the following. In the SOI process, as an isolation technology between transistors, there are two kinds of isolation technologies which include full trench isolation that completes isolation and partial trench isolation that partially remains a silicon layer.

When the full trench isolation is used, the transistor body becomes floating, so that control from the outside cannot be performed. On the other hand, when the partial trench isolation is used, electric potential of the body can be performed by means of electric potential fixing provided in the vicinity of the transistor element.

Then, in the SRAM cell, an example that the NMOS transistor gate and body is short-circuited, is disclosed in a document “Impact of Actively Body-bias Controlled (ABC) SOI SRAM by using Direct Body Contact Technology for Low-Voltage Application: Y. Hirano, et al., IEDM Technical Digest, pp. 35 to 38, DEC. 2003, (FIG. 1)”.

Now, search operation of the thus-configured CAM cell will be described.

When the node A1 of the data memory part DM is at H level and the node A2 is at L level, logic “0” is set; when the node A1 is at L level and the node A2 is at H level, logic “1” is set.

Further, in an initial state, the match line ML is precharged to H level. Then, data logic provided on the search line SL and data logic stored in the data memory part DM are compared at the data comparison part DC. When the data are matched, the match line ML holds H level to detect “match”. Conversely, when the data are unmatched, the match line ML is transited to L level to detect “mismatch”.

First, the data memory part DM is set to store data of logic “0”. In this case, since the node A1 is at H level, the node O3 also becomes H level, thus the NMOS transistor N7 of the data comparison part DC becomes an on state.

Further, since the node A2 is at L level, the node O4 also becomes L level, thus the NMOS transistor N5 of the data comparison part DC becomes an off state. Here, when the search line SL is at L level (data of logic “0” is provided), the search line \overline{SL} becomes H level. Therefore, the NMOS transistor N8 becomes an off state; the NMOS transistor N6 becomes an on state.

Since the NMOS transistors N5 and N8 of the data comparison part DC become an off state, the match line ML holds H level to detect a match between the data provided on the search line SL and the data stored in the data memory part DM.

On the other hand, when the search line SL is at H level (logic “1”), the search line \overline{SL} becomes L level. Therefore, the NMOS transistor N8 becomes an on state; the NMOS transistor N6 becomes an off state.

In this case, since the NMOS transistors N7 and N8 of the data comparison part DC become an on state, the match line ML is grounded to transit a state from H level to L level. As a result, a mismatch of data between the data provided on the search line SL and the data stored in the data memory part DM.

Operation in the case that the data memory part DM holds data of logic “1” is the same as in the case of logic “0”, and therefore, its detail explanation will not be repeated.

Now, effects by using the data comparison part DC in which the transistor short-circuited between the gate and the body is used will be described.

When the search line SL is at L level, potential difference between the gate and the source of the NMOS transistor N8 is 0 V. Further, since the body and the gate of the NMOS transistor N8 are short-circuited, potential difference between the body and the source also becomes 0 V. Therefore, it becomes the same state as the off state of an ordinary transistor whose gate and body are not short-circuited.

Next, when the search line SL is raised to a voltage level of H level (VSE), potential difference between the gate and the source becomes VSE. If the potential difference is larger than a threshold voltage, the NMOS transistor N8 becomes an on state.

At this time, potential difference between the body and the source of the NMOS transistor N8 also becomes VSE. Therefore, the NMOS transistor N8 becomes so-called a forward bias state, so that the threshold voltage becomes a lowered state. Since a turn-on current is proportional to the square of the difference between the gate voltage and the threshold voltage, as a result of lowering the threshold voltage, the turn-on current of the NMOS transistor N8 can be made larger than that of the case that the gate and the body are not short-circuited.

That is, by the short-circuiting between the gate and the body, a threshold of the NMOS transistor N8 varies according to the electric potential of the gate, so that a large on/off current ratio with excellent transistor characteristics can be obtained.

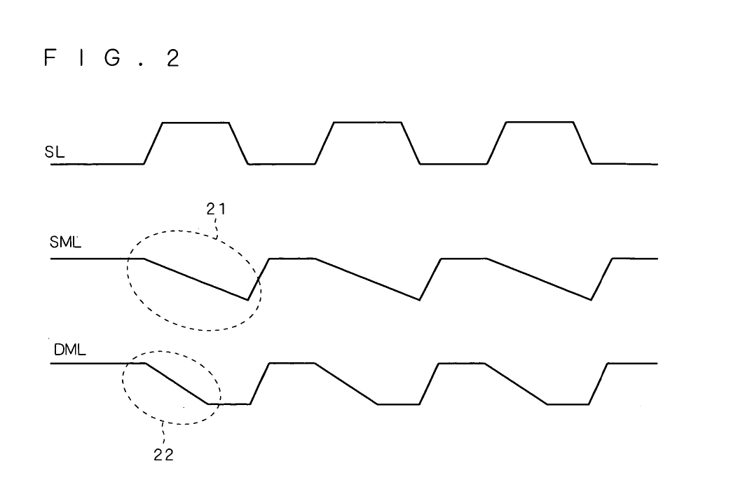

FIG. 2 is a view showing a voltage waveform of the search line SL when drive voltages of the search line SL and the match line ML are lowered, and voltage waveforms of the search line SL and the match line ML. Here, a voltage waveform of the match line ML in the case of using an ordinary NMOS transistor whose gate and body are not short-circuited is referred to as a waveform SML; a voltage waveform of the match line ML in the case of short-circuiting the body and the gate is referred to as a waveform DML.

Further, the data memory part DM is set to hold data of logic “0”, and the NMOS transistor N7 is set to become an on state.

When the search line SL transits from L level to H level, the NMOS transistor N8 transits from an off state to an on state, and discharges the match line ML which is at H level.

As shown by broken lines 21 of FIG. 2, when an ordinary NMOS transistor is used, it takes some time to discharge the match line ML because turn-on current of the NMOS transistor N8 is small, whereby a waveform SML of the match line ML becomes blunt.

On the contrary, when the body and the gate are short-circuited, the discharge of the match line ML can be performed fast because the turn-on current can be made large as described before, whereby a less blunted waveform DML can be obtained as shown by broken lines 22 of FIG. 2.

When attempt is made to enable lowering of power consumption of the CAM, the most important attempt is to realize lowering of voltage of the search line SL and the match line ML. In a known content addressable memory, as shown in FIG. 2, discharge speed of the match line ML becomes slow with the lowering of voltage, thereby lowering search speed.

In this embodiment, since the transistor whose gate and body are short-circuited is used, fast search operation can be performed even if lowering of voltage is realized.

### Second Embodiment

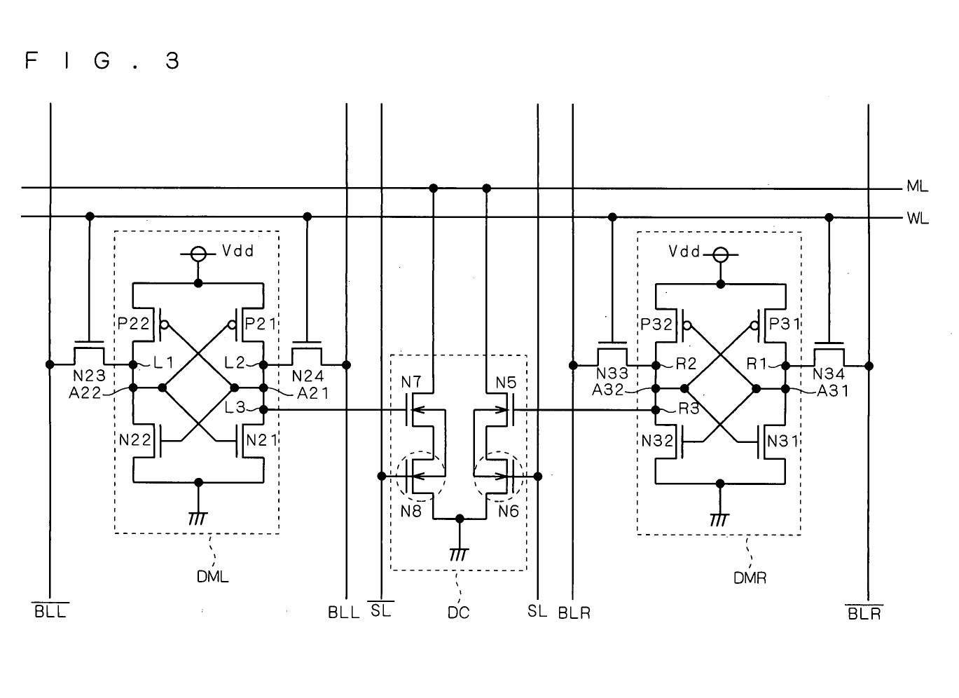

A second embodiment is a CAM applying the present invention according to the first embodiment to a Ternary CAM (TCAM) which is a memory cell capable of ternary storing. FIG. 3 is a circuit diagram showing a configuration of the TCAM according to this embodiment. The TCAM includes a data memory part DML, a DMR, and a data comparison part DC.

A drain of an NMOS transistor N23 is connected to a drain of a PMOS transistor P22, which constitutes the data memory part DML, at a node L1. A source of the NMOS transistor N23 is connected to a bit line \overline{BLL}. Then, a gate of the NMOS transistor N23 is connected to a word line WL.

A gate of an NMOS transistor N24 is further connected to the word line WL. A drain of the NMOS transistor N24 is connected to a drain of a PMOS transistor P21, which constitutes the data memory part DML, at a node L2. A source of the NMOS transistor N24 is connected to a bit line BLL.

A gate of an NMOS transistor N33 is connected to the word line WL and a source thereof is connected to a bit line BLR. A drain of the NMOS transistor N33 is connected to a drain of a PMOS transistor P32, which constitutes the data memory part DMR, at a node R2.

A gate of an NMOS transistor N34 is further connected to the word line WL. A drain of the NMOS transistor N34 is connected to a drain of a PMOS transistor P31, which constitutes the data memory part DMR, at a node R1. A source of the NMOS transistor N34 is connected to a bit line \overline{BLR}.

The gate of the NMOS transistor N5 of the data comparison part DC is connected to a drain of an NMOS transistor N32, which constitutes the data memory part DMR, at a node R3.

The drain of the NMOS transistor N5 is connected to the match line ML and the source thereof is connected to the drain of the NMOS transistor N6.

The source of the NMOS transistor N6 is grounded and the gate is connected to the search line SL. The body of the NMOS transistor N6 is short-circuited to the gate thereof and is connected to the body of the NMOS transistor N5.

The drain of the NMOS transistor N7, which constitutes the data comparison part DC, is connected to the match line ML. The source of the NMOS transistor N7 is connected to the drain of the NMOS transistor N8. The gate of the NMOS transistor N7 is connected to a drain of an NMOS transistor N21, which constitutes the data memory part DML, at a node L3.

The source of the NMOS transistor N8 is grounded and the gate thereof is connected to the search line \overline{SL}. The body of the NMOS transistor N8 is short-circuited to the gate thereof and is connected to the body of the NMOS transistor N7.

The data memory part DML includes the following configuration.

A source of the PMOS transistor P21 is connected to the power supply voltage Vdd and the drain thereof is connected to the drain of the NMOS transistor N21. Then, a source of the NMOS transistor N21 is grounded. A gate of the PMOS transistor P21 is connected to a gate of the NMOS transistor N21 and together connected to the drain of the PMOS transistor P22 and a drain of an NMOS transistor N22 at a node A22.

A source of the PMOS transistor P22 is connected to the power supply voltage Vdd and the drain thereof is connected to the drain of the NMOS transistor N22. A source of the NMOS transistor N22 is grounded. A gate of the PMOS transistor P22 is connected to a gate of the NMOS transistor N22 and together connected to the drain of the PMOS transistor P21 and the drain of the NMOS transistor N21 at a node A21.

Further, the data memory part DMR includes the following configuration.

A source of the PMOS transistor P31 is connected to the power supply voltage Vdd and the drain thereof is connected to a drain of the NMOS transistor N31. Then, a source of the NMOS transistor N31 is grounded. A gate of the PMOS transistor P31 is connected to a gate of the NMOS transistor N31 and together connected to the drain of the PMOS transistor P32 and the drain of the NMOS transistor N32 at a node A32.

A source of the PMOS transistor P32 is connected to the power supply voltage Vdd and the drain thereof is connected to the drain of the NMOS transistor N32. A source of the NMOS transistor N32 is grounded. A gate of the PMOS transistor P32 is connected to a gate of the NMOS transistor N32 and together connected to the drain of the PMOS transistor P31 and the drain of the NMOS transistor N31 at a node A31.

The TCAM is capable of storing three logic states. More specifically, the three logic states are: a logic “1” state that logic “1” is stored in the data memory part DML and logic “0” is stored in the data memory part DMR; a logic “0” state that logic “0” is stored in the data memory part DML and logic “1” is stored in the data memory part DMR; and a “don't care” state that logic “0” is stored in the data memory part DML and logic “0” is stored in the data memory part DMR.

Here, the data memory part DML sets the logic “1” state when electric potential of the node L3 is at H level and the logic “0” state when the electric potential of the node L3 is at L level. Further, the data memory part DMR sets the logic “1” state when electric potential of the node R3 is at H level and the logic “0” state when the electric potential of the node L3 is at L level.

Next, search operation of the thus-configured TCAM will be described. As in the first embodiment, the match line ML is precharged to H level in an initial state. First, the TCAM stores logic “1”. That is, logic “1” is stored in the data memory part DML and logic “0” is stored in the data memory part DMR. At this time, the NMOS transistor N5 of the data comparison part DC becomes an off state and the NMOS transistor N7 becomes an on state.

When the search line SL is at H level (logic “1”), the NMOS transistor N6 becomes an on state and the NMOS transistor N8 becomes an off state. Since the NMOS transistors N5 and N8 become an off state, a path to ground the match line ML does not exist. Therefore, the match line ML holds H level to detect “match”.

When the search line SL is at L level (logic “0”), the NMOS transistor N8 becomes an on state and the match line ML is grounded via the NMOS transistors N7 and N8 to transit from H level to L level. As a result, “mismatch” is detected. Search operation in the case that the TCAM stores logic “0” is the same as in the case of logic “1”, and therefore its detail description will not be repeated.

When the TCAM stores logic “don't care”, logic “0” is concurrently stored in the data memory parts DML and DMR. Therefore, since the electric potential of the nodes L3 and R3 becomes L level, the NMOS transistor N5 and N7 become an off state. As a result, a path to constantly ground the match line ML does not exist regardless of the \overline{SL} state, the match line ML holds H level and thus constantly detects “match” state.

Also in this embodiment, as in the first embodiment, the data comparison part DC uses the transistor whose gate and body are short-circuited is used. As a result, since turn-on current of the transistor can be made large, the discharge of the match line ML can be performed fast even if the drive voltages of the search line SL and \overline{SL} are reduced. Therefore, a less blunted voltage waveform of the match line ML can be obtained and fast search operation can be performed.

### Third Embodiment

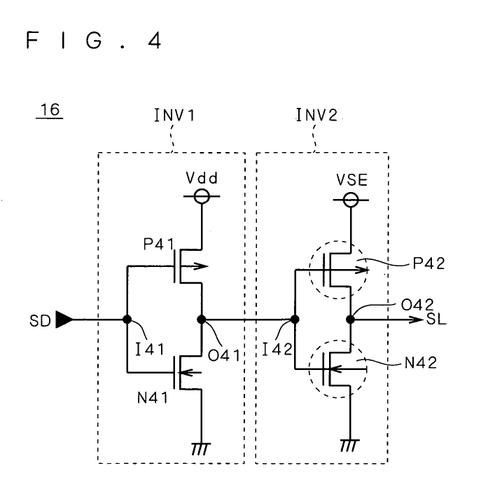

FIG. 4 is a circuit diagram showing a search line driver 16 according to this embodiment. The search line driver 16 is a drive circuit for driving the search line SL and the \overline{SL}, and is composed by an inverter INV1 and an inverter INV2.

The inverter INV1 has an input terminal 141 to which search data SD for driving the search line SL is inputted and an output terminal O41 connected to an input terminal I42 of the inverter INV2. An output terminal O42 of the inverter INV2 is connected to the search line SL.

Now, a configuration of the inverter INV1 will be described. A source of a PMOS transistor P41 is connected to the power supply voltage Vdd. A drain of the PMOS transistor P41 is connected to a drain of an NMOS transistor N41 at the output terminal O41. Then, a source of the NMOS transistor N41 is grounded. Gates of the PMOS transistor P41 and the NMOS transistor N41 are connected to the input terminal I41 to which the search data SD is inputted.

Next, a configuration of the inverter INV2 will be described. A source of a PMOS transistor P42 is connected to the power supply voltage VSE. A drain of the PMOS transistor P42 is connected to a drain of an NMOS transistor N42 at the output terminal O42. A source of the NMOS transistor N42 is grounded.

Gates of the PMOS transistor P42 and the NMOS transistor N42 are connected at the input terminal I42 which is connected to output terminal O41 of the inverter INV1. Further, a gate and a body of the PMOS transistor P42 are short-circuited and a gate and a body of the NMOS transistor N42 are also short-circuited.

Here, a voltage of the power supply voltage VSE is lower than that of the power supply voltage Vdd.

When search data SD is transited from L level to H level, the PMOS transistor P41 transits from an on state to an off state. Then, the NMOS transistor N41 transits from an off state to an on state. As a result, electric potential of the output terminal O41 is transited from H level (power supply voltage Vdd) to L level (ground potential).

When the electric potential of the output terminal O41 is transited from H level to L level; the PMOS transistor P42, which constitutes the inverter INV2, transits from an off state to an on state. Further, the NMOS transistor N42 transits from an on state to an off state. As a result, electric potential of the output terminal O42 is raised from L level (ground potential) to H level (power supply voltage VSE). Then, electric potential of the search line SL is raised up to the power supply voltage VSE.

Since the case that the search data SD is transited from H level to L level, is the same as in the case of being transited from L level to H level, their detail description will not be repeated.

As described above, when a transit signal which is transited from L level to H level is inputted, the search line driver drives the search line SL up to the power supply voltage VSE.

As shown in FIG. 4, the search line driver 16 according to this embodiment, in the former stage, uses the inverter INV1 constituted by an ordinary MOS transistor whose gate and body are not short-circuited. Further, in the final stage, the inverter INV2 constituted by a MOS transistor whose gate and body are short-circuited is used.

The search data SD is at a voltage level higher than that of the power supply voltage VSE which is used for the inverter INV2 in the final stage. When gate potential is raised, current may flow in the NMOS transistor whose gate and body are short-circuited from the gate to the body and further from the body to the source. Similarly, current may also flow in the PMOS transistor whose gate and body are short-circuited in a path from the gate to the body and further from the body to the drain.

More specifically, a pn junction is formed between the body and the source. Therefore, for example, in the case of the NMOS transistor whose gate and body are short-circuited, since the gate and the body are short-circuited, a forward voltage is applied between the body (P type) and the source (N type) when a positive voltage is applied to the gate. As a result, when a voltage larger than built-in potential is applied between the body and the source; a large current flows between the body and the source.

The search line driver 16 according to this embodiment first receives an input of the search data SD at the inverter INV1 using an ordinary MOS transistor whose gate and body are not short-circuited, then converts to a signal of the voltage Vdd, and therefore it is free from fears of flowing current from the body to the source.

Lowering of voltage of the search line SL is important for lowering of power of the CAM. However, when the lowering of voltage is simply performed, a drive power of the search line driver 16 in which the search data SD is provided on the search line SL to drive degrades.

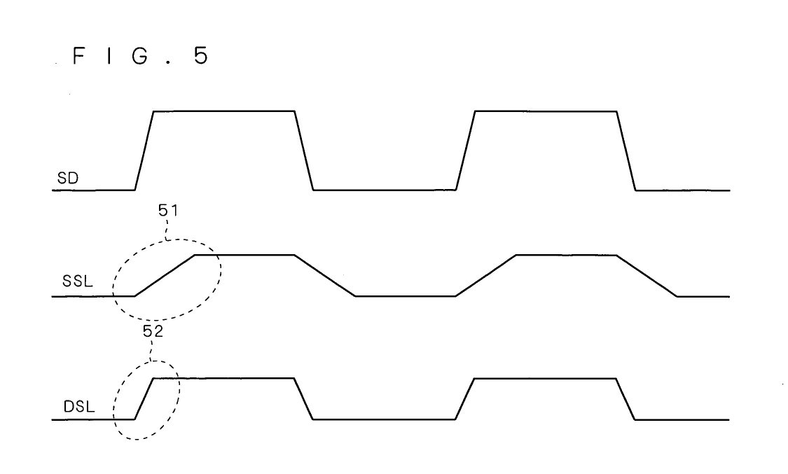

For example, as shown in broken lines 51 of a voltage waveform SSL in FIG. 5, a waveform of the search line SL becomes blunt and thus it becomes difficult to realize fast search.

Here, FIG. 5 shows a voltage waveform of the search data SD and voltage waveforms of the search line SL. A waveform SSL shows a voltage waveform of the search line SL driven by the search line driver 16 whose drive voltage is simply lowered. Further, a waveform DSL shows a waveform of the search line SL driven by the search line driver 16 according to this embodiment.

When the MOS transistor whose gate and body are short-circuited is used in the search line driver 16, the search line can be charged fast because turn-on current is made large even if the drive voltage is lowered, whereby a less blunted voltage waveform can be obtained. However, as described before, a current (a leakage current) may flow from the gate to the body.

The search line driver 16 according to this embodiment receives the search data at the inverter INV1 in the former stage, and therefore there is no problem to flow a leakage current. Further, since the inverter INV2 for driving the search line SL uses the transistor whose gate and body are short-circuited, there is no problem on the blunted voltage waveform. Therefore, when the search line driver according to this embodiment is used, a drive voltage can be lowered without reducing a drive speed of the search line SL and a content addressable memory with low voltage and high speed can be realized.

### Fourth Embodiment

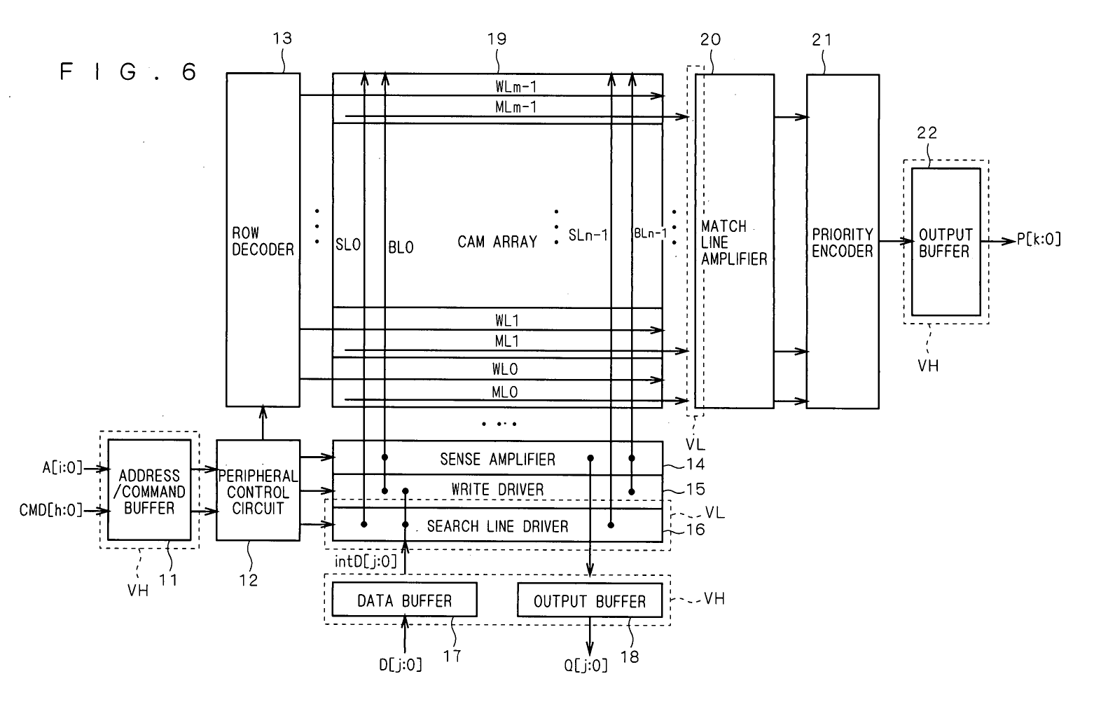

FIG. 6 is a view showing an overall view of a content addressable memory according to this embodiment.

Outputs of an address/command buffer 11 are inputted to a peripheral control circuit 12. Outputs of a peripheral control circuit 12 are inputted to a row decoder 13, a sense amplifier 14, a write driver 15, and a search line driver 16. Outputs of a data buffer 17 are connected to the search line driver 16 and the write driver 15. Further, the sense amplifier 14 is connected to an output buffer 18.

A plurality (n in the example of the drawing) of search lines SL (SL0 to SLn-1) are connected to the search line driver 16. Each of the search line SL is connected to a memory cell (not shown in the figure) which constitutes a CAM array 19.

Further, a plurality (n in an example of the drawing) of bit lines BL (BL0 to BLn-1) are connected to the sense amplifier 14 and the write driver 15. Respective bit lines BL are connected to a plurality of memory cells which constitute the CAM array 19.

A plurality (m in the example of the drawing) of word lines WL are connected to the row decoder 13, each of the word lines WL is connected to the memory cell.

Further, a plurality of match lines ML (ML0 to MLm-1) are connected to the respective memory cells and connected to a match line amplifier 20. The match line amplifier 20 is connected to a priority encoder 21 whose output is connected to an output buffer 22.

The address/command buffer 11 transmits address/command data, inputted from an outside of a chip, to the peripheral control circuit 12. Then, the peripheral control circuit 12 generates control signals based on addresses and commands for determining operation of the chip transmitted from the address/command buffer 11 and supplies them to the row decoder 13, sense amplifier 14, write driver 15, and search line driver 16. For example, when a search operation command is inputted, the peripheral control circuit 12 generates a signal to activate the search line driver 16.

Now, an operating voltage at each section, which constitutes the CAM, will be described.

The address/command buffer 11, data buffer 17, and output buffers 18 and 22 operate at the highest voltage level (VIO: 2.5 V, for example). The peripheral circuit portion and CAM cell array (a storage section) operate at an intermediate voltage level (VCORE: 1.2 V, for example).

The search line driver 16 operates at the lowest voltage level (VSE: 0.5 V, for example) for the lowering of voltage of the search line SL. The match line amplifier 20 is composed of two kinds of voltage level regions, a region which operates at the voltage VSE and a region which operates by converting the voltage level from the voltage VSE to the voltage VCORE.

Here, in FIG. 6, a region surrounded by broken lines VH denotes the region operated at the highest voltage level VIO; and a region surrounded by broken lines VL denotes the region operated at the lowest voltage level VSE. Further, a region not surrounded by broken lines denotes the region operated at the intermediate voltage level.

The specific configuration of the search line driver 16 is described in the third embodiment, and therefore its detail description will not be repeated. A configuration of the match line amplifier 20 will be described in detail below.

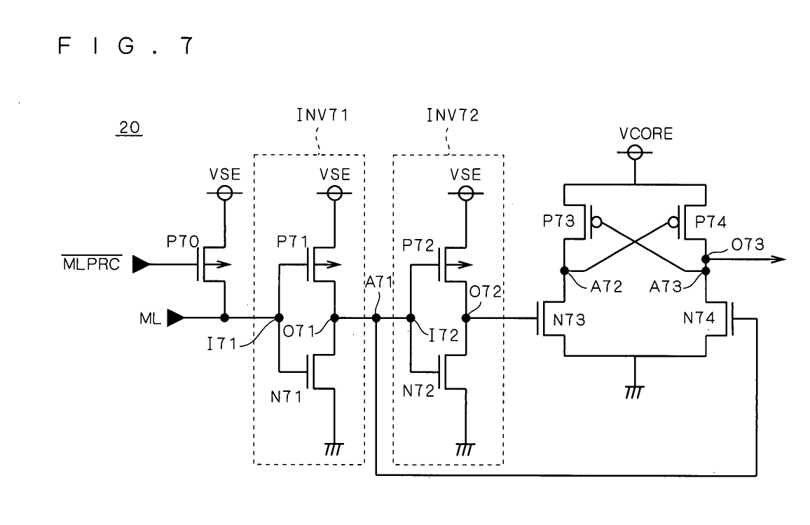

FIG. 7 is a circuit diagram showing a configuration of the match line amplifier 20 according to this embodiment. A source of a PMOS transistor P71 is connected to the power supply voltage VSE and a drain thereof is connected to the match line ML. A precharge signal \overline{MLPRC} for charging the match line ML is inputted to a gate of the PMOS transistor P71.

The match line ML is connected to an input terminal I71 of an inverter INV71 and an output terminal O71 of the inverter INV71 is connected to an input terminal I72 of an inverter INV72.

An output terminal O72 of the inverter INV72 is connected to a gate of an NMOS transistor N73. A source of an NMOS transistor N73 is grounded and a drain thereof is connected to a drain of a PMOS transistor P73 at a node A72.

A source of a PMOS transistor P74 is connected to the power supply voltage VCORE and a gate thereof is connected to a drain of the NMOS transistor N73 and a drain of a PMOS transistor P73 at a node A72.

A source of the PMOS transistor P73 is connected to the power supply voltage VCORE and a gate thereof is connected to a drain of the NMOS transistor N74 and a drain of the PMOS transistor P74 at a node A73.

A source of an NMOS transistor N74 is grounded and a gate thereof is connected to the output terminal O71 of the inverter INV71 and the input terminal I72 of the inverter INV72 at a node A71.

Now, configurations of the inverter INV71 and the inverter INV72 will be described.

The inverter INV71 is composed of the PMOS transistor P71 and the NMOS transistor N71. The source of the PMOS transistor P71 is connected to the power supply voltage VSE and the drain thereof is connected to a drain of the NMOS transistor N71 at the output terminal O71. A source of the NMOS transistor N71 is grounded. Gates of the PMOS transistor P71 and the NMOS transistor N71 are connected at the input terminal I71.

The inverter INV72 is composed of the PMOS transistor P72 and the NMOS transistor N72. The source of the PMOS transistor P72 is connected to the power supply voltage VSE and the drain thereof is connected to a drain of the NMOS transistor N72 at the output terminal O72. A source of the NMOS transistor N72 is grounded. Gates of the PMOS transistor P72 and the NMOS transistor N72 are connected at the input terminal I72.

Now, operation of the thus-configured match line amplifier 20 will be described. The match line amplifier 20 operates so as to amplify a signal from the match line ML or so as to charge the match line ML.

Prior to search operation of the CAM, when a precharge signal \overline{MLPRC} becomes L level; a PMOS transistor P70 transits to on state to charge the match line ML to the VSE.

When the search operation is performed, the signal level of the match line ML is detected to output by performing level conversion to the signal provided from an output terminal O73 at the power supply voltage VCORE.

That is, the signal of the match line ML is outputted by performing level conversion so that the signal to which H level is provided at the power supply voltage VSE and L level is provided at 0 V is converted to a signal to which H level is provided at the power supply voltage VCORE and L level is provided at 0 V.

Operation of the match line amplifier 20 will be described in detail below.

In the case that the match line ML is at H level, the inverter INV71 outputs an L level signal to the inverter INV72 and the gate of the NMOS transistor N74. The NMOS transistor N74 receives the L level signal to become an off state.

Further, the inverter INV72 receives an output of the inverter INV71 to output H level signal to the gate of the NMOS transistor N73 by reversing. The NMOS transistor N73 transits to an on state and the node 72 becomes the ground potential. Since the gate of the PMOS transistor P74 is connected to the node 72, the PMOS transistor P74 transits to an on state to raise electric potential of the node 73 up to the power supply voltage VCORE. As a result, an H level (VCORE) signal is outputted from the output terminal 073.

When the match line ML is transited to L level, the inverter INV71 outputs an H level signal to the inverter INV72 and the gate of the NMOS transistor N74. The NMOS transistor N74 receives the H level signal to become an on state. As a result, the node 73 becomes L level and the output terminal O73 outputs an L level signal.

To summarize the above-mention, in the case that the match line ML is at H level provided at the power supply voltage VSE, the match line amplifier outputs an H level signal provided at the power supply voltage VCORE.

Further, in the case that the match line ML is at L level (0 V), the match line amplifier outputs an L level (0 V) signal.

Both the CAM cell of FIG. 1 and the TCAM cell of FIG. 3 are composed by the data memory parts DM, DML and DMR (SRAM cell) and the data comparison part DC.

For lowering of power of the CAM, the search line SL and the match line ML are operated by performing the lowering of voltage. At this time, even if the data memory part DM performs the lowering of voltage, it does not almost affect the CAM power consumption during search. Of the operation of the CAM and TCAM, most parts are used for search operation because operation such as writing and reading is not very performed.

Therefore, operation without performing the lowering of voltage of the data memory part DM is desirable for fast search operation.

For example, in the case of the memory cell shown in FIG. 1, when the lowering of voltage of the data memory part DM is not performed; the electric potential at the gate of the NMOS transistor N5 and N7 is maintained with sufficiently high potential.

The turn-on current of the NMOS transistor N5 and N7 is increased by maintaining the electric potential at the gate of the NMOS transistor N5 and N7 with sufficiently high potential, thereby enabling the match line ML to be fast discharged. As a result, the data memory part DM can also increase search speed compared to the case of performing the lowering of voltage.

This embodiment does not perform the lowering of voltage of the data memory part DM, but the lowering of voltage of the whole CAM chip can be performed without reducing the search speed by performing the lowering of voltage of the operating voltage of the search line driver 16 and the match line amplifier 20.

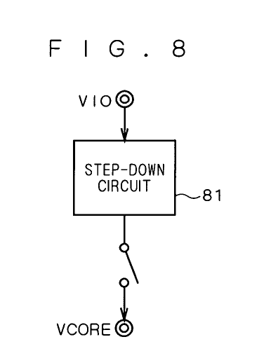

Further, a known content addressable memory currently put to practical use prepares two power supplies with different voltage levels, voltage VIO and VCORE, from outside. However, this embodiment is required to prepare three power supplies with different voltage levels from outside. In this case, as shown in FIG. 8, different voltage levels can be made by lowering voltage of a power supply voltage VCORE having comparatively small power consumption by a step-down circuit 81 inside a chip from a power supply voltage VIO. This does not require the power supply voltage VCORE supplied from outside, thereby enabling operation by a configuration having only two power supplies.

### Fifth Embodiment

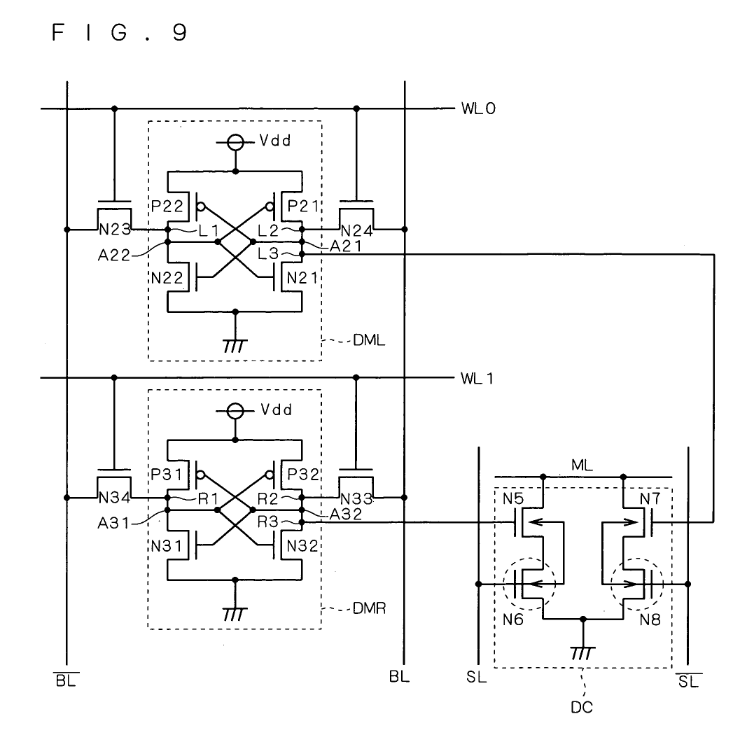

FIG. 9 is a circuit diagram showing a TCAM according to a fifth embodiment. Gates of NMOS transistors N23 and N24, which constitute a data memory part DML, are connected to a word line WLO. Then, gates of NMOS transistors N33 and N34, which constitute a data memory part DMR, are connected to a word line WL1.

Sources of the NMOS transistors N24 and N33 are connected to a bit line BL. Then, sources of the NMOS transistors N23 and N24 are connected to a bit line \overline{BL}.

That is, in a TCAM according to a fifth embodiment, the word line WLO and the word line WL1 are respectively provided with the data memory part DML and the data memory part DMR; and the bit line BL and the bit line \overline{BL} are commonly provided with the data memory part DML and the data memory part DMR.

The rest configuration is the same as in the case of the second embodiment, the same reference numerals or characters are given to the same configuration, and overlapped description will not be repeated.

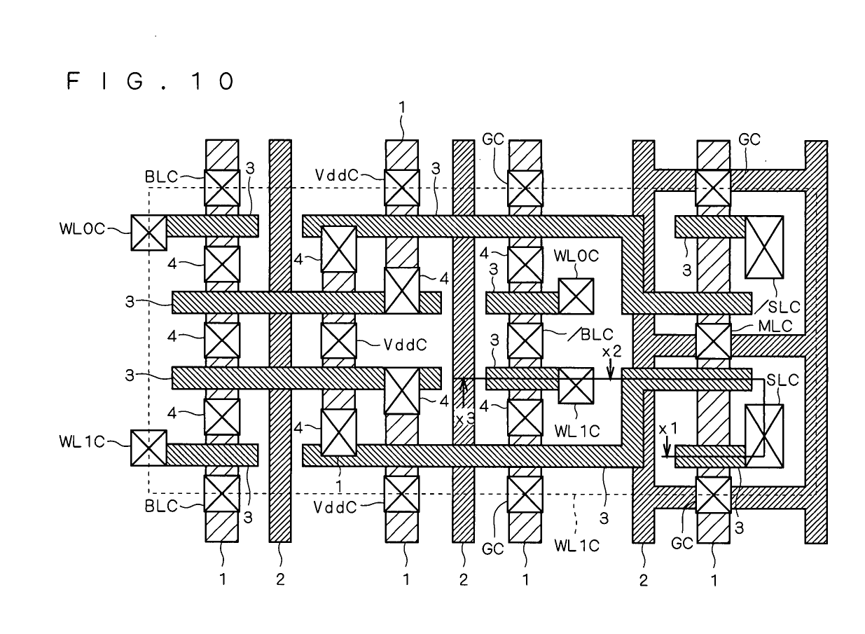

FIG. 10 is a layout view which shows a planar layout of the TCAM shown in FIG. 9. A regions surrounded by broken lines in FIG. 10 corresponds to one of the TCAMs. In FIG. 10, a configuration above a metal layer of the TCAM will be omitted.

The gate 3 is formed on a diffusion area 1. Contact holes 4, for connecting a diffusion area 1 to a metal layer, a GC, a VddC, a BLC, a \overline{BLC}, a WL0C, and a WL1C are provided.

The contact hole GC is a contact hole for connecting the diffusion area 1 to the metal layer to be connected to the GND. Then, the contact hole VddC is a contact hole for connecting the diffusion area 1 to the metal layer to be connected to the power supply voltage Vdd.

Then, the contact holes BLC and \overline{BLC} are contact holes for connecting the diffusion area 1 to the bit line BL and the \overline{BL}, respectively. The contact holes WL0C and WL1C are contact hole for connecting the diffusion area 1 to the word lines WLO and WL1, respectively.

Further, a tungsten plug SLC and a \overline{SLC} connect the search line SLC and the \overline{SLC} to the gate 3 and a silicon layer 7 between the NMOS transistors N6 and N8, respectively (refer to FIG. 1 to be described later).

Then, in full trench isolation 9 (corresponding to full trench isolation 2 in FIG. 10), a portion between elements which constitute the TCAM is completely electrically isolated.

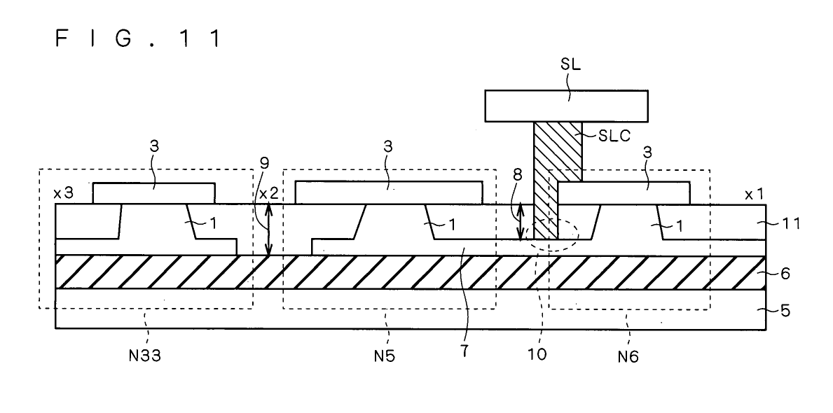

FIG. 11 is a sectional view taken along the line X1-X3 of FIG. 10. A buried oxide film 6 is formed on a substrate 5. Then, the diffusion area 1 is formed on the buried oxide film 6.

A portion between the line X1-X2 corresponds to a cross-sectional view of portions of the NMOS transistors N5 and N6 of the data comparison part DC. As shown in FIG. 9, since a portion between the diffusion area 1 of the NMOS transistors N5 and N6 is formed by the very thin silicon layer 7 having a thickness of approximately 100 nm, a portion between the diffusion area 1 of the NMOS transistors N5 and N6 is not completely electrically isolated. Therefore, this region is called as partial trench isolation 8.

Whereas, the silicon layer 7 is completely removed at X2 and an oxide film 11 is deposited. Then, a portion between the NMOS transistor N5 and N33 is completely electrically isolated. Therefore, a portion corresponding to the X2 is called as full trench isolation 9.

Then, the search line SL is formed on an upper layer of the gate 3 and the search line SL is connected to the gate 3 and the silicon layer 7 via the tungsten plug SLC. Here, a connection portion between the tungsten plug SLC and the silicon layer 7, is called as a direct body contact 10.

Since search operation of the TCAM according to the fifth embodiment is the same as the operation of the TCAM according to the second embodiment, their detail description will not be repeated.

As described above, in the TCAM according to the fifth embodiment, the portion between the diffusion area 1 of the NMOS transistors N5 and N6, which constitutes the data comparison part DC, is isolated by the partial trench isolation 8.

Therefore, the portion between the diffusion area 1 of the NMOS transistors N5 and N6 is not completely electrically isolated; thus, electric potential of the bodies of the NMOS transistors N5 and N6 become the same.

Then, in the TCAM according to the fifth embodiment, the bodies of the NMOS transistors N5 and N6 and the search line SL, the gate 3 are short-circuited by the tungsten plug SLC.

Therefore, in the TCAM according to the fifth embodiment, electric potential state of the search line SL can be directly transmitted to the bodies of the NMOS transistors N5 and N6.

As a result, the TCAM according to the fifth embodiment can operate at low voltage and at high speed.

Further, manufacturing methods of the partial trench isolation and the direct body contact are disclosed in a document “Impact of Actively Body-bias Controlled (ABC) SOI SRAM by using Direct Body Contact Technology for Low-Voltage Application: Y Hirano, et al., IEDM Technical Digest, pp. 35-38, DEC. 2003”.

In addition, the direct body contact 10 can also be applied to the CAM and the TCAM of other embodiments to realize the lowering of voltage and faster operation as in the TCAM of this embodiment.

What is claimed is:

1. A content addressable memory formed on an SOI substrate, comprising:
a plurality of memory cells;
a match line connected to said memory cell; and
a search line connected to said memory cell, wherein
said memory cell includes:
a data memory part; and
a data comparison part for comparing data stored in said data memory part with search data provided on said search line,
said data comparison part includes a transistor whose gate is connected to said search line and discharges said match line by conducting, and
said transistor has a gate and a body being short-circuited.

2. The content addressable memory according to claim 1, wherein
said memory cell further includes a second data memory part capable of storing three different states by combining with said data memory part.

3. The content addressable memory according to claim 1, further comprising:
a search line driver for driving said search line in response to said search data, wherein
said search line driver includes:
a first inverter to which said search data is inputted; and
a second inverter to which an output of said first inverter is inputted, and
said second inverter is driven by a low power supply voltage lower than a power supply voltage for driving said first inverter and includes a transistor having a gate and a body being short-circuited.

4. The content addressable memory according to claim 3, wherein
said match line and said search line are driven by said low power supply voltage,
the content addressable memory further comprising a match line amplifier connected to said match line, for outputting by amplifying electric potential level of said match line.
